(19) United States
(12) Patent Application Publication
(10) Pub. No.: US 2026/0254431 A1
(43) Pub. Date: Aug. 27, 2026

(54) ELECTRONIC COMPONENT

(71) Applicant: TDK Corporation, Tokyo (JP)

(72) Inventors: Jun NAKATSUTSUMI, Tokyo (JP); Kazuhiro TSUKAMOTO, Tokyo (JP)

(73) Assignee: TDK Corporation, Tokyo (JP)

(21) Appl. No.: 19/535,065

(22) Filed: Feb. 10, 2026

(30) Foreign Application Priority Data
Feb. 18, 2025 (JP) 2025-024468

(51) Int. Cl. H03H 7/01; H03H 1/00

(52) U.S. Cl. CPC H03H 7/0115; H03H 2001/0085

(57) ABSTRACT

An electronic component includes a first signal port, a second signal port, an LC circuit that is provided between the first signal port and the second signal port, includes at least one capacitor and at least one inductor, and is configured to cause a signal having a frequency equal to or higher than a specific frequency to pass through selectively, a first path that extends from the first signal port to the LC circuit, a second path that extends from the second signal port to the LC circuit, a first inductor that is provided between the first path and a ground, and a second inductor that is provided between the second path and the ground. The first inductor and the second inductor are physically arranged so as to be coupled to each other.

### CROSS REFERENCE TO RELATED APPLICATIONS

This application claims the benefit of Japanese Priority Patent Application No. 2025-024468 filed on February 18, 2025, the entire contents of which are incorporated herein by reference.

### BACKGROUND

The disclosure relates to an electronic component including an LC circuit configured to cause a signal having a frequency equal to or higher than a specific frequency to pass through selectively.

As an electronic component used in a communication device including a wireless communication function, a filter that causes a signal having a specific frequency to pass through selectively has been known. Examples of the filter include a high-pass filter that causes a signal having a frequency equal to or higher than a specific frequency to pass through selectively, a low-pass filter that causes a signal having a frequency equal to or lower than a specific frequency to pass through selectively, and a band-pass filter that causes a signal having a frequency within a specific frequency range to pass through selectively.

JP H08-107326 A discloses a mixer (branching filter) configured to mix and separate signals in adjacent frequency bands. The mixer (branching filter) includes a low-pass filter connected to a first terminal, and a high-pass filter and a band-pass filter connected in series to a second terminal. Each of the low-pass filter, the high-pass filter, and the band-pass filter is configured by a plurality of capacitors and a plurality of coils.

In a communication device, there is a strong demand for higher-speed wireless communication and enhanced functionality, and higher performance is also required for an electronic component used in the communication device. In addition, in recent years, a communication device has been increasingly reduced in size, and size reduction is also required for an electronic component.

In an electronic component, as described in JP H08-107326 A, a plurality of elements such as inductors and capacitors are used. In general, the number of elements is increased as performance is enhanced. In an LC circuit configured to cause a signal having a frequency equal to or higher than a specific frequency to pass through selectively, the inductance of an inductor and the capacitance of a capacitor may be increased in order to form an attenuation pole at a frequency lower than the specific frequency. As a result, the LC circuit may be increased in size.

### SUMMARY

An electronic component according to one embodiment of the disclosure includes a first signal port, a second signal port, an LC circuit that is provided between the first signal port and the second signal port, includes at least one capacitor and at least one inductor, and is configured to cause a signal having a frequency equal to or higher than a specific frequency to pass through selectively, a first path that extends from the first signal port to the LC circuit, a second path that extends from the second signal port to the LC circuit, a first inductor that is provided between the first path and a ground, and a second inductor that is provided between the second path and the ground. The first inductor and the second inductor are physically arranged so as to be coupled to each other.

Objects, features, and advantages of the disclosure will appear more fully from the following description.

### BRIEF DESCRIPTION OF THE DRAWINGS

The accompanying drawings are included to provide a further understanding of the disclosure and are incorporated in and constitute a part of this specification. The drawings illustrate example embodiments and, together with the specification, serve to explain the principles of the disclosure.

FIG. 1 is a circuit diagram showing a circuit configuration of an electronic component according to a first example embodiment of the disclosure.

FIG. 2 is a perspective view showing the electronic component according to the first example embodiment of the disclosure.

FIG. 3 is a cross-sectional view showing the electronic component according to the first example embodiment of the disclosure.

FIG. 4 is a perspective view showing a first body according to the first example embodiment of the disclosure.

FIG. 5 is a perspective view showing the first body according to the first example embodiment of the disclosure.

FIG. 6 is an explanatory diagram showing a patterned surface of a first dielectric layer of the first body according to the first example embodiment of the disclosure.

FIG. 7 is an explanatory diagram showing a patterned surface of a second dielectric layer of the first body according to the first example embodiment of the disclosure.

FIG. 8 is an explanatory diagram showing a patterned surface of a third dielectric layer of the first body according to the first example embodiment of the disclosure.

FIG. 9 is an explanatory diagram showing a patterned surface of a fourth dielectric layer of the first body according to the first example embodiment of the disclosure.

FIG. 10 is an explanatory diagram showing a patterned surface of a fifth dielectric layer of the first body according to the first example embodiment of the disclosure.

FIG. 11 is an explanatory diagram showing a patterned surface of a sixth dielectric layer of the first body according to the first example embodiment of the disclosure.

FIG. 12 is an explanatory diagram showing a patterned surface of a seventh dielectric layer of the first body according to the first example embodiment of the disclosure.

FIG. 13 is an explanatory diagram showing a patterned surface of an eighth dielectric layer of the first body according to the first example embodiment of the disclosure.

FIG. 14 is an explanatory diagram showing a patterned surface of a ninth dielectric layer of the first body according to the first example embodiment of the disclosure.

FIG. 15 is an explanatory diagram showing a patterned surface of a tenth dielectric layer of the first body according to the first example embodiment of the disclosure.

FIG. 16 is an explanatory diagram showing a patterned surface of an eleventh dielectric layer of the first body according to the first example embodiment of the disclosure.

FIG. 17 is an explanatory diagram showing a patterned surface of a twelfth dielectric layer of the first body according to the first example embodiment of the disclosure.

FIG. 18 is an explanatory diagram showing a patterned surface of a thirteenth dielectric layer of the first body according to the first example embodiment of the disclosure.

FIG. 19 is an explanatory diagram showing a patterned surface of a fourteenth dielectric layer of the first body according to the first example embodiment of the disclosure.

FIG. 20 is an explanatory diagram showing a patterned surface of a fifteenth dielectric layer of the first body according to the first example embodiment of the disclosure.

FIG. 21 is an explanatory diagram showing a patterned surface of a sixteenth layer of the first body according to the first example embodiment of the disclosure.

FIG. 22 is an explanatory diagram showing a patterned surface of a seventeenth layer of the first body according to the first example embodiment of the disclosure.

FIG. 23 is an explanatory diagram showing a surface opposite to the patterned surface of the seventeenth layer of the first body according to the first example embodiment of the disclosure.

FIG. 24 is a perspective view showing an inside of the first body according to the first example embodiment of the disclosure.

FIG. 25 is a characteristic chart showing an example of pass attenuation characteristics of the electronic component according to the first example embodiment of the disclosure.

FIG. 26 is a circuit diagram showing a circuit configuration of an electronic component according to a second example embodiment of the disclosure.

FIG. 27 is a circuit diagram showing a circuit configuration of an electronic component in a comparative example.

FIG. 28 is a characteristic chart showing an example of pass attenuation characteristics of a model in the comparative example.

FIG. 29 is a characteristic chart showing an example of pass attenuation characteristics of a model in an example.

### DETAILED DESCRIPTION

An object of the disclosure is to provide an electronic component that can achieve size reduction while achieving desired characteristics.

In the following, some example embodiments and modification examples of the disclosure will be described in detail with reference to the accompanying drawings. Note that the following description is directed to illustrative examples of the disclosure and not to be construed as limiting the disclosure. Factors including, without limitation, numerical values, shapes, materials, components, positions of the components, and how the components are coupled to each other are illustrative only and not to be construed as limiting the disclosure. Further, elements in the following example embodiments which are not recited in a most-generic independent claim of the disclosure are optional and may be provided on an as-needed basis. The drawings are schematic and are not intended to be drawn to scale. Like elements are denoted with the same reference numerals to avoid redundant descriptions.

### First Example Embodiment

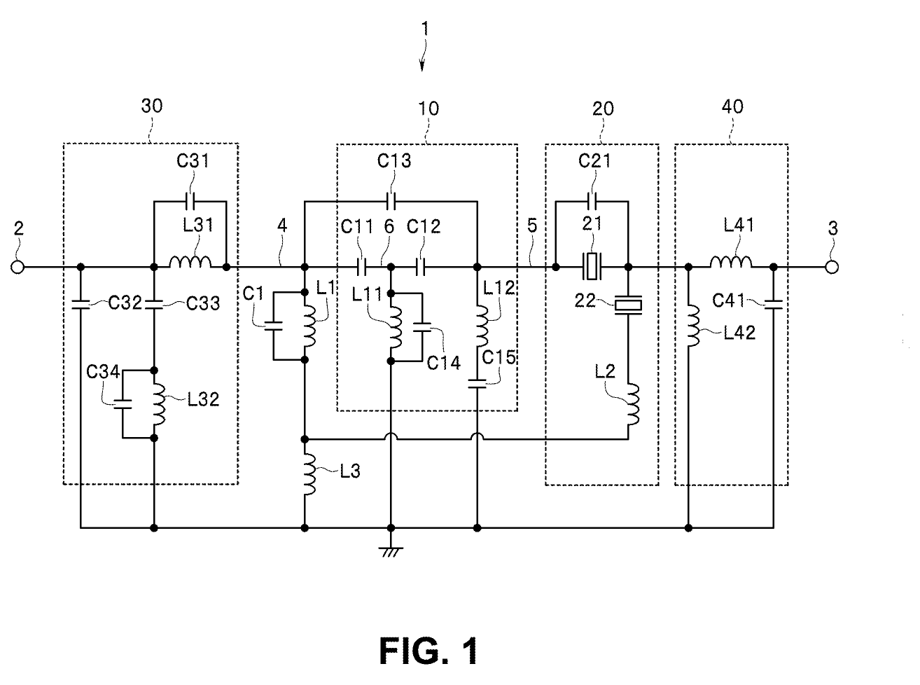

First, with reference to FIG. 1, a configuration of an electronic component according to a first example embodiment of the disclosure is described. FIG. 1 is a circuit diagram showing an electronic component 1 according to the example embodiment. Note that, in the following description, the expression “in a circuit configuration" is used to describe an arrangement in a circuit diagram, not in a physical configuration.

The electronic component 1 includes a first signal port 2, a second signal port 3, an LC circuit 10, a first path 4, and a second path 5. Each of the first and second signal ports 2 and 3 is a signal port for input or output of a signal. Specifically, when a signal is input to the first signal port 2, a signal is output from the second signal port 3. When a signal is input to the second signal port 3, a signal is output from the first signal port 2.

The LC circuit 10 is provided between the first signal port 2 and the second signal port 3, in a circuit configuration. The LC circuit 10 includes at least one capacitor and at least one inductor, and is configured to cause a signal having a frequency equal to or higher than a specific frequency to pass through selectively.

The first path 4 is a path that extends from the first signal port 2 to the LC circuit 10, and connects the first signal port 2 and the LC circuit 10 to each other, in a circuit configuration. The second path 5 is a path that extends from the second signal port 3 to the LC circuit 10, and connects the second signal port 3 and the LC circuit 10 to each other, in a circuit configuration.

The electronic component 1 further includes an inductor L1 that is provided between the first path 4 and the ground, in a circuit configuration. The inductor L1 corresponds to a “first inductor” in the disclosure. The inductor L1 is connected to the at least one capacitor of the LC circuit 10. The electronic component 1 further includes a capacitor C1 that is connected in parallel to the inductor L1. Note that, in the example embodiment, a capacitor that is connected in series directly or indirectly to the inductor L1 is not provided between the first path 4 and the ground.

The electronic component 1 further includes an inductor L2 that is provided between the second path 5 and the ground, in a circuit configuration. The inductor L2 corresponds to a “second inductor” in the disclosure. The inductor L1 and the inductor L2 are physically arranged so as to be coupled to each other. The coupling between the inductor L1 and the inductor L2 may be magnetic coupling. In FIG. 1, a reference numeral L3 indicates the magnetic coupling between the inductor L1 and the inductor L2. The physical arrangement of the inductor L1 and the inductor L2 is described below.

In the example embodiment, a capacitor that is connected in series directly or indirectly to the inductor L2 may not be provided between the second path 5 and the ground.

The electronic component 1 further includes three circuits 20, 30, and 40 that are provided between the first signal port 2 and the second signal port 3, in a circuit configuration. The circuit 20 is provided between the LC circuit 10 and the second signal port 3, in a circuit configuration. The circuit 30 is provided between the LC circuit 10 and the first signal port 2, in a circuit configuration. The circuit 40 is provided between the circuit 20 and the second signal port 3, in a circuit configuration.

The circuit 20 includes the inductor L2 and at least one element that is provided between the LC circuit 10 and the inductor L2. The at least one element may be, for example, an inductor element, a capacitor element, or an acoustic wave element. The acoustic wave element may be a bulk acoustic wave element or a surface acoustic wave element.

In the example embodiment, the LC circuit 10 and the inductors L1 and L2, and at least one of the three circuits 20, 30, and 40 form a band-pass filter that causes a signal having a frequency within a specific passband to pass through selectively. With reference to FIG. 1, an example of a circuit configuration of the electronic component 1 being a band-pass filter is described below.

The circuit 30 includes capacitors C31, C32, C33, and C34 and inductors L31 and L32. The inductor L31 is provided to the first path 4. One end of the inductor L31 is connected to the first signal port 2. The capacitor C31 is connected in parallel to the inductor L31.

One end of the capacitor C32 and one end of the capacitor C33 are connected to one end of the inductor L31. One end of the inductor L32 is connected to the other end of the capacitor C33. The capacitor C34 is connected in parallel to the inductor L32. The other end of the capacitor C32 and the other end of the inductor L32 are connected to the ground.

The LC circuit 10 includes a third path 6 that connects the first path 4 and the second path 5 to each other. As the at least one capacitor and the at least one inductor, the LC circuit 10 includes the capacitors C11, C12, C13, C14, and C15 and inductors L11 and L12.

The capacitors C11 and C12 are provided to the third path 6. One end of the capacitor C11 is connected to the other end of the inductor L31 of the circuit 30. One end of the capacitor C12 is connected to the other end of the capacitor C11.

The capacitor C13 is connected to the capacitors C11 and C12. One end of the capacitor C13 is connected to one end of the capacitor C11. The other end of the capacitor C13 is connected to the other end of the capacitor C12.

The inductor L11 is provided between the third path 6 and the ground. One end of the inductor L11 is connected to the third path 6 between the capacitor C11 and the capacitor C12. The capacitor C14 is connected in parallel to the inductor L11. The other end of the inductor L11 is connected to the ground.

One end of the inductor L12 is connected to the other end of the capacitor C12. One end of the capacitor C15 is connected to the other end of the inductor L12. The other end of the capacitor C15 is connected to the ground.

The inductor L1 is connected to the first path 4 between the LC circuit 10 and the circuit 30. One end of the inductor L1 is connected to one end of the capacitor C11. The capacitor C1 is connected in parallel to the inductor L1. The other end of the inductor L1 is connected to the ground.

As the at least one element, the circuit 20 includes two acoustic wave elements 21 and 22. The circuit 20 further includes a capacitor C21 and the inductor L2.

The acoustic wave element 21 is provided to the second path 5. One end of the acoustic wave element 21 is connected to the other end of the capacitor C12 of the LC circuit 10. The capacitor C21 is connected in parallel to the acoustic wave element 21.

The acoustic wave element 22 is provided between the second path 5 and the ground. One end of the acoustic wave element 22 is connected to the other end of the acoustic wave element 21. One end of the inductor L2 is connected to the other end of the acoustic wave element 22. The other end of the inductor L2 is connected to the ground.

The circuit 40 includes a capacitor C41 and inductors L41 and L42. The inductor L41 is provided to the second path 5. One end of the inductor L42 is connected to the other end of the acoustic wave element 21 of the circuit 20. The other end of the inductor L41 is connected to the second signal port 3.

One end of the inductor L42 is connected to one end of the inductor L41. One end of the capacitor C41 is connected to the other end of the inductor L41. The other end of the inductor L42 and the other end of the capacitor C41 are connected to the ground.

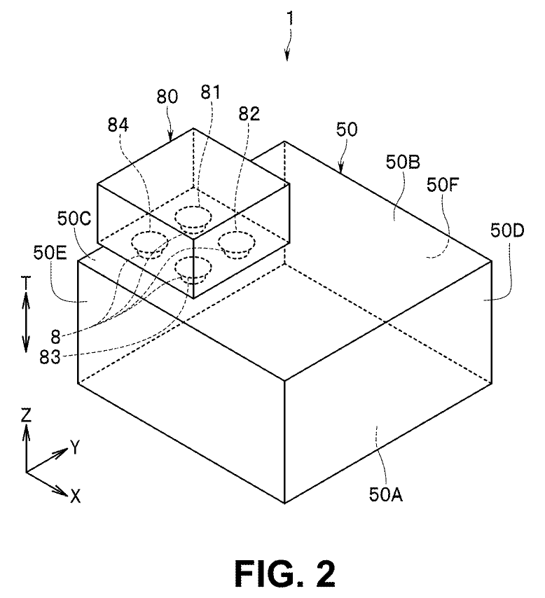

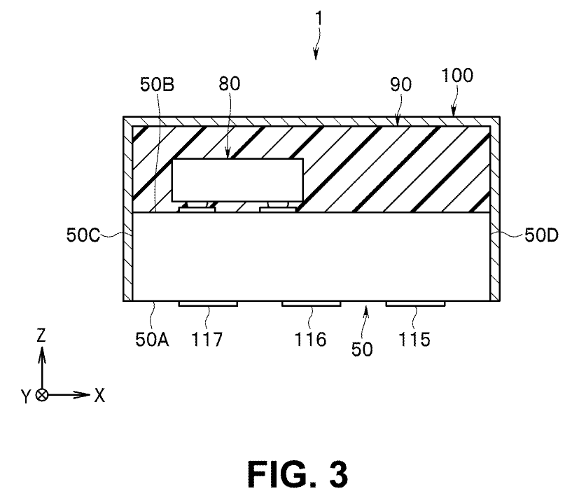

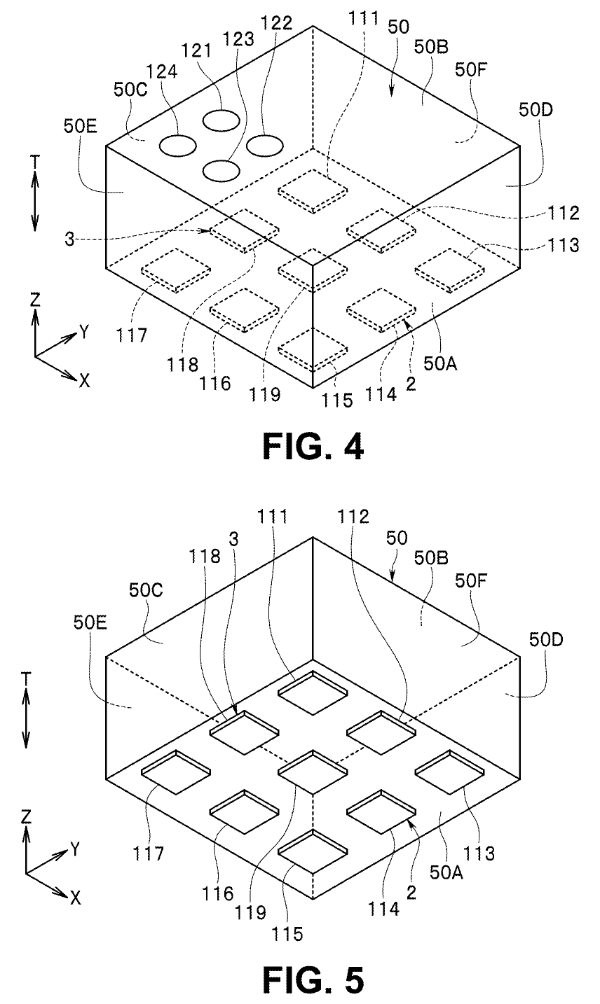

Next, with reference to FIGS. 2 to 5, other configurations of the electronic component 1 are described. FIG. 2 is a perspective view showing the electronic component 1. FIG. 3 is a cross-sectional view showing the electronic component 1. FIGS. 4 and 5 are each a perspective view showing a first body of the electronic component 1.

The electronic component 1 according to the example embodiment includes a first body 50 and a second body 80 mounted on the first body 50. The first body 50 includes a stack including a plurality of dielectric layers stacked and a plurality of conductors (a plurality of conductor layers and a plurality of through holes). As such a dielectric material, for example, a low temperature co-fired ceramic (LTCC) is used.

The first body 50 includes components other than the acoustic wave elements 21 and 22 among the components of the electronic component 1 shown in FIG. 1. The second body 80 includes the acoustic wave elements 21 and 22.

The first body 50 includes a bottom surface 50A that is located at one end in a stacking direction T of the plurality of dielectric layers, a top surface 50B that is located at the other end in the stacking direction T, and four side surfaces 50C to 50F that connect the bottom surface 50A and the top surface 50B to each other. The side surfaces 50C and 50D face opposite to each other, and the side surfaces 50E and 50F also face opposite to each other. The side surfaces 50C to 50F are perpendicular to the bottom surface 50A and the top surface 50B.

Here, X, Y, and Z directions are defined as shown in FIGS. 2 to 5. The X, Y, and Z directions are orthogonal to one another. In the example embodiment, a direction parallel to the stacking direction T is referred to as the Z direction. The Z direction is also a direction parallel to a direction in which the first body 50 and the second body 80 are arrayed. The opposite directions to the X, Y, and Z directions are defined as −X, −Y, and −Z directions, respectively. The expression "when seen in a specific direction (for example, the stacking direction T)" means that an intended object is seen from a position at a distance in the specific direction or a direction parallel to the specific direction.

As shown in FIG. 4 and FIG. 5, the bottom surface 50A is located at the end of the first body 50 in the −Z direction. The top surface 50B is located at the end of the first body 50 in the Z direction. The top surface 50B also serves as a mounting surface on which the second body 80 is mounted. FIG. 4 shows the first body 50 as viewed from the top surface 50B side. FIG. 5 shows the first body 50 as viewed from the bottom surface 50A side.

The side surface 50C is located at the end of the first body 50 in the −X direction. The side surface 50D is located at the end of the first body 50 in the X direction. The side surface 50E is located at the end of the first body 50 in the −Y direction. The side surface 50F is located at the end of the first body 50 in the Y direction.

The first body 50 further includes a plurality of electrodes 111, 112, 113, 114, 115, 116, 117, 118, and 119 provided on the bottom surface 50A of the first body 50. The electrodes 111, 112, and 113 are arrayed in this order in the X direction at positions closer to the side surface 50F than the side surface 50E. The electrodes 115, 116, and 117 are arrayed in this order in the −X direction at positions closer to the side surface 50E than the side surface 50F.

The electrode 114 is arranged between the electrode 113 and electrode 115. The electrode 118 is arranged between the electrode 111 and electrode 117. The electrode 119 is arranged between the electrode 112 and electrode 116. The electrode 119 is arranged substantially at the center of the bottom surface 50A.

The electrode 114 corresponds to the first signal port 2. The electrode 118 corresponds to the second signal port 3. Accordingly, the first signal port 2 and the second signal port 3 are provided on the bottom surface 50A of the first body 50. Each of the electrodes 111 to 113, 115 to 117, and 119 is connected to the ground.

The first body 50 further includes electrodes 121, 122, 123, and 124 provided on the top surface 50B of the first body 50. The plurality of electrodes 121 to 124 are used for electrically connecting the first body 50 and the second body 80 to each other. The electrodes 121 and 122 are arrayed in this order in the X direction. The electrodes 123 and 124 are arranged in front of the electrodes 121 and 122 in the −Y direction, and are arrayed in this order in the −X direction.

The second body 80 further includes four electrodes 81, 82, 83, and 84. In a state where the second body 80 is mounted on the first body 50, the electrodes 81 to 84 are respectively opposed to the electrodes 121 to 124 of the first body 50. The electrodes 81 to 84 are physically connected to the electrodes 121 to 124 with solder bumps 8, for example.

The electronic component 1 further includes a protective layer 90. The protective layer 90 covers the second body 80 and the top surface 50B of the first body 50. As the material of the protective layer 90, an insulating material containing a resin material may be used. The resin material may be a thermosetting resin or a thermoplastic resin.

The electronic component 1 further includes a shield layer 100 formed of a conductive material. The shield layer 100 covers the first body 50, the second body 80, and the protective layer 90. The shield layer 100 contacts with the side surfaces 50C to 50F of the first body 50. The conductive material may be pure metal composed of a single metal element, or an alloy composed of a plurality of metal elements. The shield layer 100 may include a plurality of layers, each of which is formed of an insulating material.

The shield layer 100 is electrically connected to the electrodes 111 to 113, 115 to 117, and 119. The first body 50 includes a plurality of conductors that electrically connect the shield layer 100 and the electrodes 111 to 113, 115 to 117, and 119 to each other.

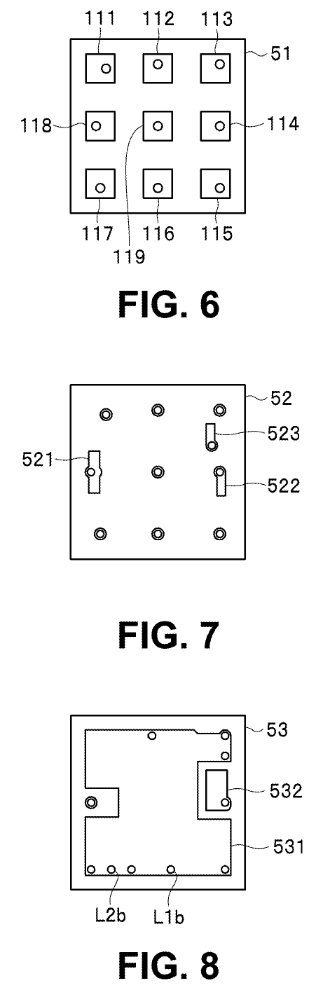

Next, with reference to FIGS. 6 to 23, an example of the plurality of dielectric layers, the plurality of conductor layers, and the plurality of through holes included in the first body 50 are described. In this example, the first body 50 includes seventeen dielectric layers stacked. Hereinafter, the seventeen dielectric layers are referred to as first to seventeenth dielectric layers in the order from bottom to top. The first to seventeenth dielectric layers are denoted by reference numerals 51 to 67, respectively.

In FIGS. 6 to 23, a plurality of circles (a singly drawn circle and an inner circle of two concentrically drawn circles) represent the plurality of through holes. The dielectric layers 51 to 67 each include a plurality of through holes formed therein. The plurality of through holes are each formed by filling a hole intended for a through hole with a conductive paste. In FIGS. 6 to 23, a plurality of shapes other than the plurality of circles representing the plurality of through holes represent the plurality of plurality of dielectric layers, the plurality of conductor layers, and the plurality of electrodes. Each of the plurality of through holes is connected to an electrode, a conductor layer, or another through hole.

In FIGS. 6 to 23, among the plurality of through holes, reference numerals are respectively assigned to a plurality of specific through holes that form a plurality of specific parts described below. A reference numeral assigned to a through hole indicates that the through hole is a component of one of the plurality of specific portions. A connection relation of each of the plurality of specific through holes, and a conductor layer or another through hole is described as a connection relation in a state where the first to seventeenth dielectric layers 51 to 67 are stacked. Among the plurality of through holes to which the same reference numeral is assigned, two through holes that are vertically adjacent to each other in the stacking direction T are connected to each other.

FIG. 6 shows a patterned surface of the first dielectric layer 51. The patterned surface of the dielectric layer 51 includes the electrodes 111 to 119 formed. FIG. 7 shows a patterned surface of the second dielectric layer 52. The patterned surface of the dielectric layer 52 includes conductor layers 521, 522, and 523 formed.

FIG. 8 shows a patterned surface of the third dielectric layer 53. The patterned surface of the dielectric layer 53 includes conductor layers 531 and 532 formed. In the dielectric layer 53, the through hole denoted with the reference numeral L1b and the through hole denoted with the reference numeral L2b are formed. The through hole denoted with the reference numeral L1b and the through hole denoted with the reference numeral L2b are connected to the conductor layer 531.

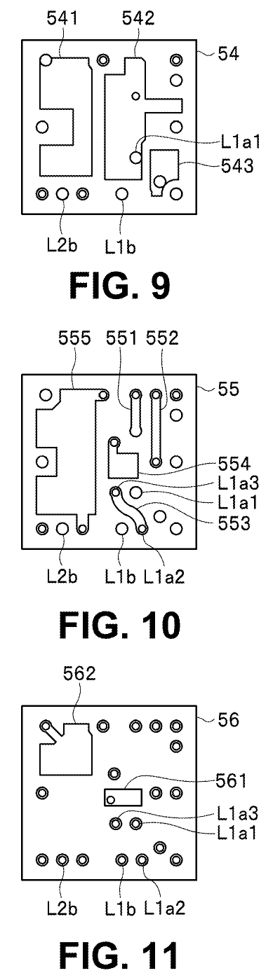

FIG. 9 shows a patterned surface of the fourth dielectric layer 54. The patterned surface of the dielectric layer 54 includes conductor layers 541, 542, and 543 formed. In the dielectric layer 54, the through hole denoted with the reference numeral L1a1, the through hole denoted with the reference numeral L1b, and the through hole denoted with the reference numeral L2b are formed. The through hole denoted with the reference numeral L1a1 is connected to the conductor layer 542.

FIG. 10 shows a patterned surface of the fifth dielectric layer 55. The patterned surface of the dielectric layer 55 includes inductor conductor layers 551, 552, and 553 and conductor layers 554 and 555 formed. In the dielectric layer 55, the through hole denoted with the reference numeral L1a1, the through hole denoted with the reference numeral L1a2, the through hole denoted with the reference numeral L1a3, the through hole denoted with the reference numeral L1b, and the through hole denoted with the reference numeral L2b are formed. The through hole denoted with the reference numeral L1a2 and the through hole denoted with the reference numeral L1a3 are connected to the conductor layer 553.

FIG. 11 shows a patterned surface of the sixth dielectric layer 56. The patterned surface of the dielectric layer 56 includes conductor layers 561 and 562 formed. In the dielectric layer 56, the through hole denoted with the reference numeral L1a1, the through hole denoted with the reference numeral L1a2, the through hole denoted with the reference numeral L1a3, the through hole denoted with the reference numeral L1b, and the through hole denoted with the reference numeral L2b are formed.

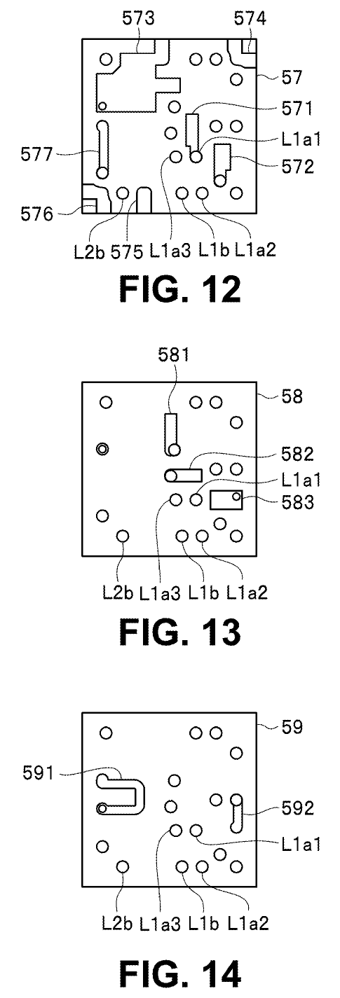

FIG. 12 shows a patterned surface of the seventh dielectric layer 57. The patterned surface of the dielectric layer 57 includes a conductor layer 571, 572, 573, 574, 575, 576, and 577 formed. Each of the conductor layers 573 to 576 is connected to the shield layer 100. In the dielectric layer 57, the through hole denoted with the reference numeral L1a1, the through hole denoted with the reference numeral L1a2, the through hole denoted with the reference numeral L1a3, the through hole denoted with the reference numeral L1b, and the through hole denoted with the reference numeral L2b are formed. The through hole denoted with the reference numeral L1a1 is connected to the conductor layer 571.

FIG. 13 shows a patterned surface of the eighth dielectric layer 58. The patterned surface of the dielectric layer 58 includes a conductor layer 581, 582, and 583 formed. In the dielectric layer 58, the through hole denoted with the reference numeral L1a1, the through hole denoted with the reference numeral L1a2, the through hole denoted with the reference numeral L1a3, the through hole denoted with the reference numeral L1b, and the through hole denoted with the reference numeral L2b are formed.

FIG. 14 shows a patterned surface of the ninth dielectric layer 59. The patterned surface of the dielectric layer 59 includes an inductor conductor layer 591 and a conductor layer 592 formed. In the dielectric layer 59, the through hole denoted with the reference numeral L1a1, the through hole denoted with the reference numeral L1a2, the through hole denoted with the reference numeral L1a3, the through hole denoted with the reference numeral L1b, and the through hole denoted with the reference numeral L2b are formed.

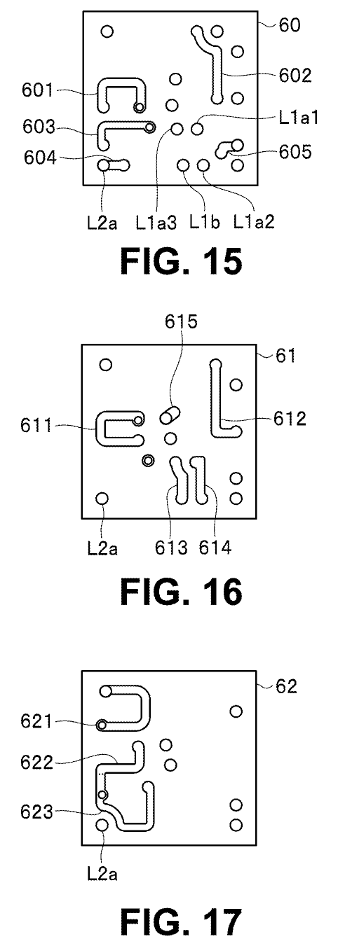

FIG. 15 shows a patterned surface of the tenth dielectric layer 60. The patterned surface of the dielectric layer 60 includes inductor conductor layers 601, 602, 603, and 604 and a conductor layer 605 formed. In the dielectric layer 60, the through hole denoted with the reference numeral L1a1, the through hole denoted with the reference numeral L1a2, the through hole denoted with the reference numeral L1a3, the through hole denoted with the reference numeral L1b, and the through hole denoted with the reference numeral L2a are formed. The through hole denoted with the reference numeral L2b formed in the dielectric layer 59 and the through hole denoted with the reference numeral L2a are connected to the conductor layer 604.

FIG. 16 shows a patterned surface of the eleventh dielectric layer 61. The patterned surface of the dielectric layer 61 includes inductor conductor layers 611, 612, 613, and 614 and a conductor layer 615 formed. The two through holes denoted with the reference numerals L1a3 and L1b formed in the dielectric layer 60 are connected to the conductor layer 613. The two through holes denoted with the reference numerals L1a1 and L1a2 formed in the dielectric layer 60 are connected to the conductor layer 614. In the dielectric layer 61, the through hole denoted with the reference numeral L2a is formed.

FIG. 17 shows a patterned surface of the twelfth dielectric layer 62. The patterned surface of the dielectric layer 62 includes inductor conductor layers 621, 622, and 623 formed. The conductor layer 622 is connected to the conductor layer 623. In FIG. 17, the boundary between the conductor layer 622 and the conductor layer 623 is indicated by the dotted line. In the dielectric layer 62, the through hole denoted with the reference numeral L2a is formed.

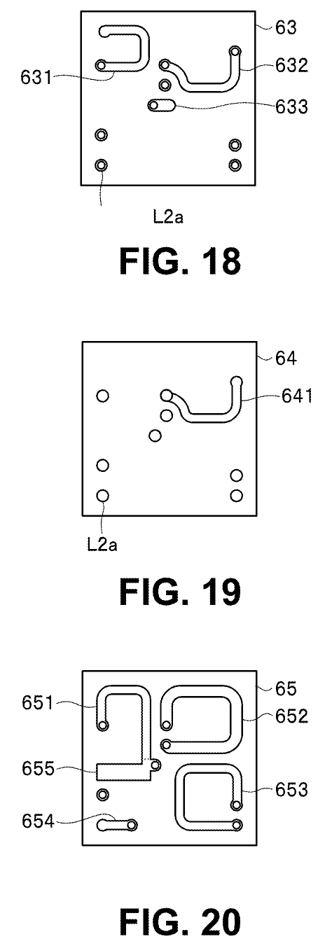

FIG. 18 shows a patterned surface of the thirteenth dielectric layer 63. The patterned surface of the dielectric layer 63 includes inductor conductor layers 631 and 632 and a conductor layer 633 formed. In the dielectric layer 63, the through hole denoted with the reference numeral L2a is formed.

FIG. 19 shows a patterned surface of the fourteenth dielectric layer 64. The patterned surface of the dielectric layer 64 includes an inductor conductor layer 641 formed. In the dielectric layer 64, the through hole denoted with the reference numeral L2a is formed.

FIG. 20 shows a patterned surface of the fifteenth dielectric layer 65. The patterned surface of the dielectric layer 65 includes inductor conductor layers 651, 652, and 653 and conductor layers 654 and 655 formed. The conductor layer 651 is connected to the conductor layer 655. In FIG. 20, the boundary between the conductor layer 651 and the conductor layer 655 is indicated by the dotted line. The through hole denoted with the reference numeral L2a formed in the dielectric layer 64 is connected to the conductor layer 654.

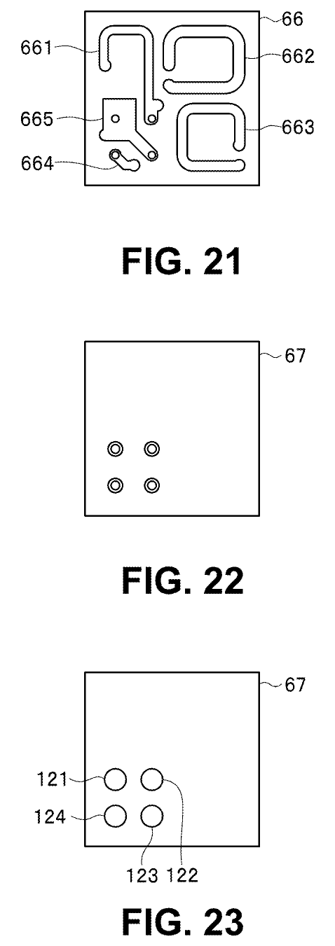

FIG. 21 shows a patterned surface of the sixteenth dielectric layer 66. The patterned surface of the dielectric layer 66 includes inductor conductor layers 661, 662, and 663 and conductor layers 664 and 665 formed.

FIG. 22 shows a patterned surface of the seventeenth dielectric layer 67. FIG. 23 shows a terminal formation surface being a surface opposite to the patterned surface of the seventeenth dielectric layer 67. The electrodes 121 to 124 are formed on a terminal formation surface of the dielectric layer 67.

The first body 50 shown in FIG. 2 is configured by stacking the first to seventeenth dielectric layers 51 to 67 so that the patterned surface of the first dielectric layer 51 serves as the bottom surface 50A of the first body 50, and the terminal formation surface of the seventeenth dielectric layer 67 serves as the top surface 50B of the first body 50. Note that FIGS. 6 to 23 show the shapes and arrangement of the plurality of conductor layers, the plurality of electrodes, and the plurality of through holes in a plan view from the top surface 50B side of the first body 50.

Each of the plurality of through holes shown in FIGS. 6 to 23 is, with the first to seventeenth dielectric layers 51 to 67 stacked, connected to a conductor layer overlapping in the stacking direction T or to another through hole overlapping in the stacking direction T. Among the plurality of through holes shown in FIGS. 6 to 23, a through hole located within an electrode or within a conductor layer is connected to the electrode or the conductor layer.

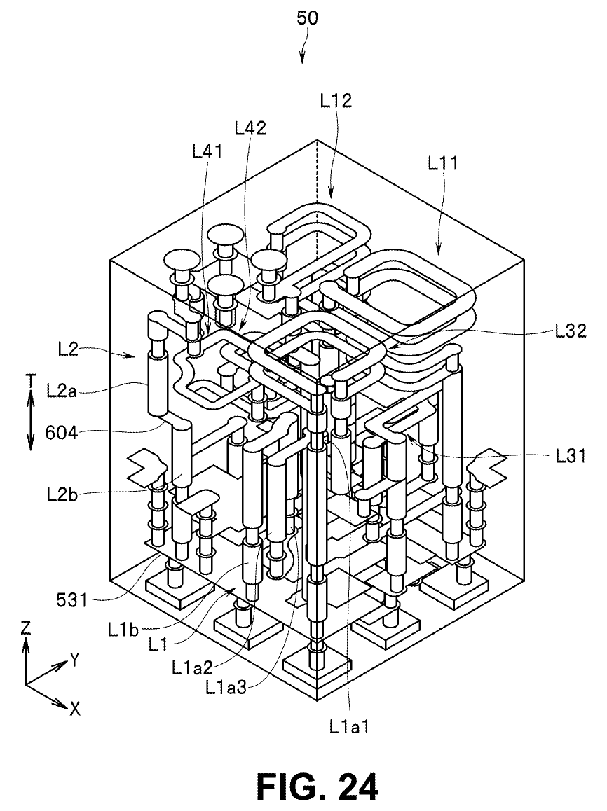

FIG. 24 shows an inside of the first body 50 including the first to seventeenth dielectric layers 51 to 67 stacked. As shown in FIG. 24, the plurality of conductor layers and the plurality of through holes shown in FIGS. 6 to 22 are stacked inside the first body 50. Note that, in FIG. 24, for convenience, the dimension of the first body 50 in the stacking direction T is drawn to be larger.

Correspondences between the components of the circuit of the electronic component 1 shown in FIG. 1 and the internal components of the first body 50 shown in FIGS. 6 to 23 are described.

The inductor L31 of the circuit 30 includes the inductor conductor layers 551, 552, 602, and 612, the plurality of through holes that connect the conductor layer 551 and the conductor layer 602 to each other, the plurality of through holes that connect the conductor layer 552 and the conductor layer 602 to each other, the plurality of through holes that connect the conductor layer 552 and the conductor layer 612 to each other, and the plurality of through holes that connect the conductor layer 532 and the conductor layer 612 to each other.

The capacitor C31 of the circuit 30 includes the conductor layers 532 and 542 and the dielectric layer 53 provided therebetween. The capacitor C32 of the circuit 30 includes the conductor layers 522 and 531 and the dielectric layer 52 provided therebetween. The capacitor C33 of the circuit 30 includes the conductor layers 572 and 583 and the dielectric layer 57 provided therebetween.

The inductor L32 of the circuit 30 includes the inductor conductor layers 653 and 663 and the plurality of through holes that connect the conductor layers 653 and 663 to each other. The capacitor C34 of the circuit 30 includes the conductor layers 531 and 543 and the dielectric layer 53 provided therebetween.

The inductor L1 includes the inductor conductor layers 553, 613, and 614 and the plurality of through holes denoted with the reference numerals L1a1, L1a2, L1a3, and L1b. The capacitor C1 includes the conductor layers 531 and 542 and the dielectric layer 53 provided therebetween.

The capacitor C11 of the LC circuit 10 includes the conductor layers 542 and 554 and the dielectric layer 54 provided therebetween. The capacitor C12 of the LC circuit 10 includes the conductor layers 554 and 561 and the dielectric layer 55 provided therebetween. The capacitor C13 of the LC circuit 10 includes the conductor layers 571 and 582 and the dielectric layer 57 provided therebetween.

The inductor L11 of the LC circuit 10 includes the inductor conductor layers 632, 641, 652, and 662 and the plurality of through holes that connect the conductor layers 632, 641, 652, and 662 to each other. The capacitor C14 of the LC circuit 10 includes the conductor layers 573 and 581 and the dielectric layer 57 provided therebetween.

The inductor L12 of the LC circuit 10 includes the inductor conductor layers 621, 631, 651, and 661 and the plurality of through holes that connect the conductor layers 621, 631, 651, and 661 to each other. The capacitor C15 of the LC circuit 10 includes the conductor layers 531 and 541 and the dielectric layer 53 provided therebetween.

One end of the acoustic wave element 21 of the circuit 20 is connected to the electrode 122. One of the other end of the acoustic wave element 21 of the circuit 20 and the one end of the acoustic wave element 22 of the circuit 20 is connected to the electrode 121. The other of the other end of the acoustic wave element 21 of the circuit 20 and the one end of the acoustic wave element 22 of the circuit 20 is connected to the electrode 123. The other end of the acoustic wave element 22 of the circuit 20 is connected to the electrode 124.

The capacitor C21 of the circuit 20 includes the conductor layers 655 and 665 and the dielectric layer 65 provided therebetween. The inductor L2 of the circuit 20 includes the inductor conductor layer 604 and the plurality of through holes denoted with the reference numerals L2a andL2b.

The inductor L41 of the circuit 40 includes the inductor conductor layers 603 and 623 and the plurality of through holes that connect the conductor layers 603 and 623 to each other. The inductor L42 of the circuit 40 includes the inductor conductor layers 591, 601, 611, and 622 and the plurality of through holes that connect the conductor layers 591, 601, 611, and 622 to each other. The capacitor C41 of the circuit 40 includes the conductor layers 521 and 531 and the dielectric layer 52 provided therebetween.

Next, with reference to FIGS. 2 to 24, structural features of the electronic component 1 according to the example embodiment are described. The inductor L1 includes three first parts L1a1, L1a2, and L1a3 and a second part L1b. The inductor L2 includes a third part L2aand a fourth part L2b. The first part L1a1 includes the plurality of through hole each of which is denoted with the reference numeral L1a1. The first part L1a2 includes the plurality of through hole each of which is denoted with the reference numeral L1a2. The first part L1a3 includes the plurality of through hole each of which is denoted with the reference numeral L1a3. The second part L1b includes the plurality of through hole each of which is denoted with the reference numeral L1b. The third part L2a includes the plurality of through hole each of which is denoted with the reference numeral L2a. The fourth part L2b includes the plurality of through hole each of which is denoted with the reference numeral L2b.

As shown in FIG. 24, each of the three first parts L1a1 to L1a3 and the second to fourth parts L1b, L2a, and L2b is a columnar conductor being a columnar structure formed by connecting the plurality of through holes in series. Each of the three first parts L1a1 to L1a3 and the second to fourth parts L1b, L2a, and L2b extends in a direction parallel to the stacking direction T.

The inductor L1 further includes the conductor layers 553, 613, and 614. The conductor layer 614 connects one end of the first part L1a1 and one end of the first part L1a2 to each other. The conductor layer 614 connects one end of the first part L1a3 and one end of the second part L1b to each other. The conductor layer 553 connects the other end of the first part L1a2 and the other end of the first part L1a3 to each other. The inductor L1 is wound about a shaft that extends in a direction orthogonal to the stacking direction T and passes through between the first part L1a1 and the first part L1a2 and between the first part L1a3 and the second part L1b.

The inductor L2 further includes the conductor layer 604. The conductor layer 604 connects one end of the third part L2a and one end of the fourth part L2b to each other.

The other end of the second part L1b of the inductor L1 and the other end of the fourth part L2b of the inductor L2 are connected to the conductor layer 531. The conductor layer 531 is connected to the electrodes 111 to 113, 115 to 117, and 119 that are connected to the ground, via the plurality of through holes. Accordingly, in the inductor L1, the second part L1b is provided between the three first parts L1a1 to L1a3 and the ground, in a circuit configuration. In the inductor L2, the fourth part L2b is provided between the third part L2a and the ground, in a circuit configuration.

Next, the physical arrangement of the inductor L1 and the inductor L2 is described. The inductor L1 and the inductor L2 are physically arranged so as to be coupled to each other. As shown in FIG. 24, in the example embodiment, another element or another conductor is not provided between at least a part of the inductor L1 and at least a part of the inductor L2.

In the example embodiment, as shown in FIG. 24, the fourth part L2b of the inductor L2 is brought closer to the inductor L1 as compared to the third part L2a of the inductor L2 so that an interval between the inductor L1 and the fourth part L2b of the inductor L2 in a plan view from the stacking direction T is smaller than an interval between the inductor L1 and the third part L2a of the inductor L2 in a plan view from the stacking direction T. In particular, in the example embodiment, an interval between the second part L1b and the fourth part L2b in a plan view from the stacking direction T is smaller than an interval between the first parts L1a1 to L1a3 and the third part L2a in a plan view from the stacking direction T.

Next, other structural features of the electronic component 1 according to the example embodiment are described. First, the inductors L11, L12, L31, L32, L41, and L42 are described. Each of the inductors L11, L12, L32, L41, and L42 is wound about a shaft that extends in a direction parallel to the stacking direction T. The inductor L31 is wound about a shaft that extends in a direction orthogonal to the stacking direction T.

Next, features relating to the shield layer 100 and the ground are described. The conductor layers 573, 574, 575, and 576 are connected to the shield layer 100. Each of the conductor layers 573, 574, 575, and 576 is connected to the conductor layers 531 via the plurality of through holes. As described above, the conductor layer 531 is connected to the electrodes 111 to 113, 115 to 117, and 119 that are connected to the ground, via the plurality of through holes. Accordingly, the shield layer 100 is connected to the ground via the plurality of conductors provided in the first body 50.

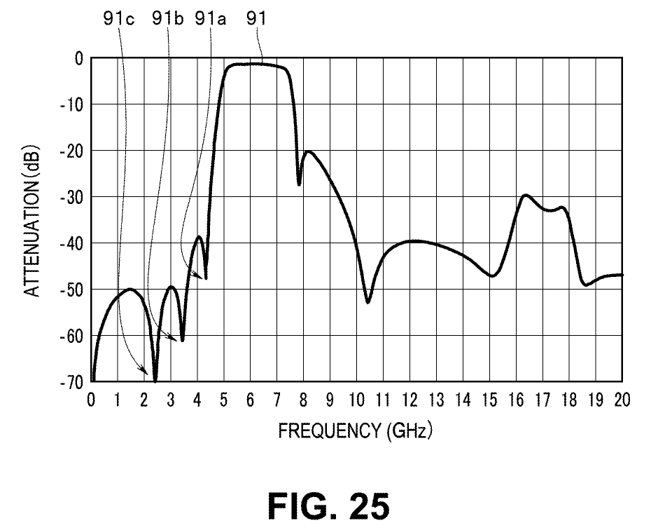

Next, an example of characteristics of the electronic component 1 according to the example embodiment is shown. Herein, description is made on characteristics of the electronic component 1 in a case in which the electronic component 1 is designed as a band-pass filter where a passband falls within a range from 5.15 GHz to 7.125 GHz. FIG. 25 is a characteristic chart showing an example of pass attenuation characteristics of the electronic component 1. In FIG. 25, the horizontal axis represents a frequency, and the vertical axis represents an attenuation amount. In FIG. 25, the curve line denoted with the reference numeral 91 represents pass attenuation characteristics between the first signal port 2 and the second signal port 3. Note that FIG. 25 shows pass attenuation characteristics when the acoustic wave elements 21 and 22 do not function in order to distinguish a plurality of attenuation poles formed by the acoustic wave elements 21 and 22 from a plurality of attenuation poles formed by parts other than the acoustic wave elements 21 and 22.

As shown in FIG. 25, in a stop band on a lower frequency side than the passband, three attenuation poles are formed. The arrow denoted with the reference numeral 91a represents an attenuation pole having the highest frequency among the three attenuation poles. Hereinafter, this attenuation pole is referred to as a first attenuation pole 91a. The arrow denoted with the reference numeral 91c represents an attenuation pole having the lowest frequency among the three attenuation poles. Hereinafter, this attenuation pole is referred to as a third attenuation pole 91c. The attenuation pole indicated by the arrow denoted with the reference numeral 91b is referred to as a second attenuation pole 91b.

The first attenuation pole 91a may be formed by the capacitors C11 to C14 and the inductor L11 of the LC circuit 10. The second attenuation pole 91b may be formed by the capacitor C15 and the inductor L12 of the LC circuit 10. The third attenuation pole 91c may be formed by the coupling between the inductor L1 and the inductor L2. The inductance of the inductor L2 may be smaller than the inductance of each of the inductors L1, L11, and L12.

Next, the operation and effects of the electronic component 1 according to the example embodiment are described. As described above, when the electronic component 1 is a band-pass filter, the plurality of attenuation poles are formed in the stop band on the lower frequency side than the passband. In the example embodiment, the LC circuit 10 is configured to cause a signal having a frequency equal to or higher than the specific frequency to pass through selectively. In other words, the LC circuit 10 includes a function of preventing a frequency lower than the specific frequency from passing through. The LC circuit 10 and the inductors L1 and L2 form the plurality of attenuation poles in the stop band on the lower frequency side than the passband. In order to form an attenuation pole at a relatively low frequency, it is necessary to increase the inductance of an inductor and the capacitance of a capacitor to some extent. For this purpose, it is necessary to increase the dimension of the inductor and the dimension of the capacitor to some extent, respectively.

In contrast, in the example embodiment, the inductor L1 and the inductor L2 are physically arranged so as to be coupled to each other. The third attenuation pole 91c is formed by the inductor L1 and the inductor L2. With this, according to the example embodiment, the electronic component 1 can be reduced in size by omitting a capacitor having a relatively large dimension. In particular, in the example embodiment, the third attenuation pole 91c is an attenuation pole having the lowest frequency in the stop band on the lower frequency side than the passband. Thus, according to the example embodiment, as compared to a case in which the inductor L2 is coupled to the inductors L11 and L12 of the LC circuit 10, it is possible to omit a capacitor having a larger dimension, and it is possible to suppress an increase in insertion loss in the passband. Note that, in a second example embodiment, it is described that, by coupling the inductor L1 and the inductor L2 to each other, characteristics equivalent to those obtained when an inductor and a capacitor are used to form an attenuation pole can be achieved.

In view of this, according to the example embodiment, the electronic component 1 can be reduced in size while achieving desired characteristics.

In the example embodiment, the inductor L2 is not a component of the LC circuit 10 but a component of the circuit 20 being another circuit. The acoustic wave elements 21 and 22 of the circuit 20 are provided between the LC circuit 10 and the inductor L2, and the inductor L2 is not directly connected to the LC circuit 10. In the example embodiment, the inductor L2 is provided between the acoustic wave element 22 and the ground. In other words, the inductor L2 is an element for connecting the acoustic wave element 22 to the ground. According to the example embodiment, compared to a case in which another inductor coupled to the inductor L1 is provided in the LC circuit 10, it is possible to reduce the number of inductors. With this, according to the example embodiment, the electronic component 1 can also be reduced in size.

### Second Example Embodiment

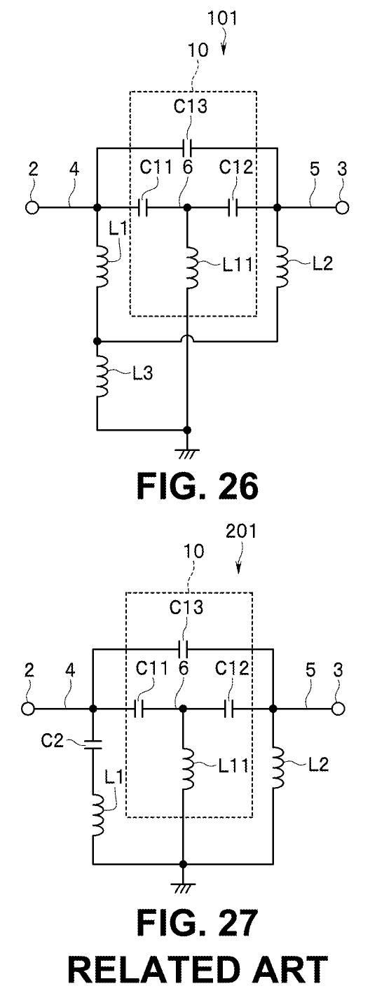

Next, with reference to FIG. 26, a second example embodiment of the disclosure is described. FIG. 26 is a circuit diagram showing a circuit configuration of the electronic component according to the example embodiment.

Similarly to the electronic component 1 according to the first example embodiment, an electronic component 101 according to an example embodiment includes the first signal port 2, the second signal port 3, the first path 4, the second path 5, and the inductors L1 and L2. The electronic component 101 includes an LC circuit 110 in place of the LC circuit 10 in the first example embodiment. In the example embodiment, the first path 4 is a path that extends from the first signal port 2 to the LC circuit 110. The second path 5 is a path that extends from the second signal port 3 to the LC circuit 110. In the example embodiment, one end of the inductor L2 is connected to the second path 5.

The configuration of the LC circuit 110 is similar to the configuration of the LC circuit 10 in the first example embodiment, except that the capacitors C14 and C15 and the inductor L12 are not provided. In other words, the LC circuit 110 includes the capacitors C11, C12, C13, and C14 and the inductor L11. In the example embodiment, the capacitor C11 is connected to the first signal port 2. The capacitor C12 is connected to the second signal port 3.

In the example embodiment, similarly to the first example embodiment, the inductor L1 and the inductor L2 are physically arranged so as to be coupled to each other. In FIG. 26, the reference numeral L3 indicates the magnetic coupling between the inductor L1 and the inductor L2.

In the example embodiment, the LC circuit 110 and the inductors L1 and L2 form a high-pass filter that causes a signal having a frequency equal to or higher than the specific frequency to pass through selectively.

Next, effects of the electronic component 101 according to the example embodiment are described with reference to simulation results. In the simulation, a model in a comparative example and a model in an example are used. The model in the comparative example is a model of an electronic component 201 in the comparative example. The model in the example is a model of the electronic component 101 according to the example embodiment.

First, with reference to FIG. 27, a configuration of the electronic component 201 in the comparative example is described. FIG. 27 is a circuit diagram showing a circuit configuration of the electronic component 201 in the comparative example. The configuration of the electronic component 201 in the comparative example is different from the configuration of the electronic component 101 according to the example embodiment in the following points. The electronic component 201 in the comparative example includes the capacitor C2 that is provided between the first path 4 and the inductor L1. In the electronic component 201 in the comparative example, the inductor L1 and the inductor L2 are not coupled to each other.

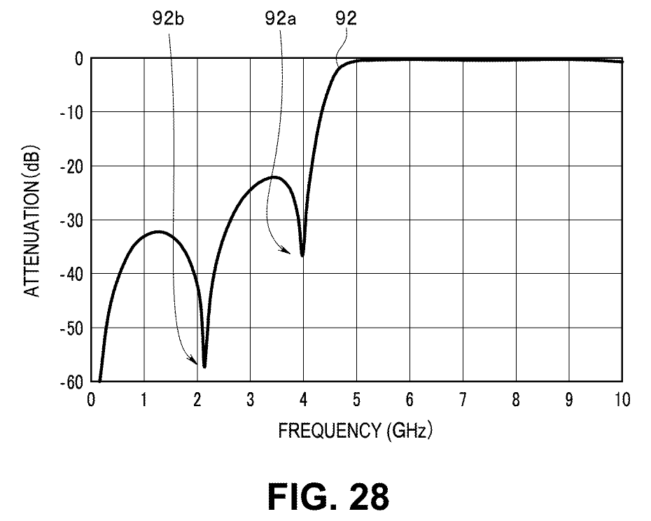

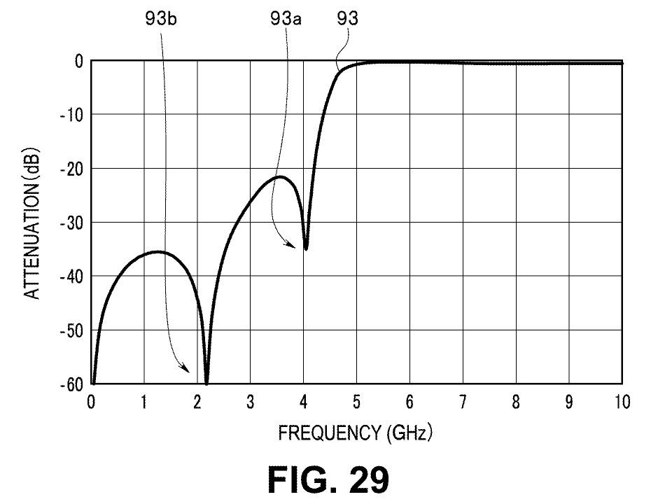

Next, the simulation results are described. In the simulation, each of the model in the comparative example and the model in the example is designed as a high-pass filter having a cutoff frequency within a range from 4.5 GHz to 4.7 GHz. FIG. 28 is a characteristic chart showing an example of pass attenuation characteristics of the model in the comparative example. FIG. 29 is a characteristic chart showing an example of pass attenuation characteristics of the model in the example. In each of FIG. 28 and FIG. 29, the horizontal axis represents a frequency, and the vertical axis represents an attenuation amount. In FIG. 28, the curve line denoted with the reference numeral 92 represents pass attenuation characteristics between the first signal port 2 and the second signal port 3 in the model in the comparative example. In FIG. 29, the curve line denoted with the reference numeral 93 represents pass attenuation characteristics between the first signal port 2 and the second signal port 3 in the model in the example.

As shown in FIG. 28, in the model in the comparative example, two attenuation poles are formed in a stop band on a lower frequency side than a cutoff frequency. The arrow denoted with the reference numeral 92a represents an attenuation pole having a higher frequency of the two attenuation poles. Hereinafter, this attenuation pole is referred to as a first attenuation pole 92a. The arrow denoted with the reference numeral 92b represents an attenuation pole having a lower frequency of the two attenuation poles. Hereinafter, this attenuation pole is referred to as a second attenuation pole 92b. The first attenuation pole 92a is formed by the capacitors C11 to C13 and the inductor L11 of the LC circuit 110. The second attenuation pole 92b is formed by series resonance of the inductor L1 and the capacitor C2.

As shown in FIG. 29, in the model in the example, two attenuation poles are formed in a stop band on a lower frequency side than a cutoff frequency. The arrow denoted with the reference numeral 93a represents an attenuation pole having a higher frequency of the two attenuation poles. Hereinafter, this attenuation pole is referred to as a first attenuation pole 93a. The arrow denoted with the reference numeral 93b represents an attenuation pole having a lower frequency of the two attenuation poles. Hereinafter, this attenuation pole is referred to as a second attenuation pole 93b. The first attenuation pole 93a is formed by the capacitors C11 to C13 and the inductor L11 of the LC circuit 110. The second attenuation pole 93b is formed by the coupling between the inductor L1 and the inductor L2.

As understood from FIG. 28 and FIG. 29, the model in the example has pass attenuation characteristics equivalent to those of the model in the comparative example. Accordingly, according to the example embodiment, while omitting the capacitor C2 by coupling the inductor L1 and the inductor L2 to each other, it is possible to achieve characteristics equivalent to those obtained when the inductor L1 and the capacitor C2 are used to form an attenuation pole. With this, according to the example embodiment, the electronic component 101 can be reduced in size while achieving desired characteristics.

Note that the effects the inductors L1 and L2 that are described with reference to the simulation results are also applied to the inductors L1 and L2 in the first example embodiment. The other configurations, operation, and effects of the example embodiment are similar to those of the first example embodiment.

Note that the disclosure is not limited to the foregoing example embodiments, and various modifications may be made thereto. For example, the inductor L1 may be coupled to an inductor provided to any one of the circuits 30 and 40, the inductor being other than the inductor L2. Similarly, the inductor L2 may be coupled to an inductor provided to the LC circuit 10, the inductor being other than the inductor L1.

As described above, an electronic component according to one embodiment of the disclosure includes a first signal port, a second signal port, an LC circuit that is provided between the first signal port and the second signal port, includes at least one capacitor and at least one inductor, and is configured to cause a signal having a frequency equal to or higher than a specific frequency to pass through selectively, a first path that extends from the first signal port to the LC circuit, a second path that extends from the second signal port to the LC circuit, a first inductor that is provided between the first path and a ground, and a second inductor that is provided between the second path and the ground, wherein the first inductor and the second inductor are physically arranged so as to be coupled to each other.

In the electronic component according to the embodiment of the disclosure, the LC circuit, the first inductor, and the second inductor may form a plurality of attenuation poles in a stop band of pass attenuation characteristics between the first signal port and the second signal port, the stop band being lower than the specific frequency. Among the plurality of attenuation poles, an attenuation pole having the lowest frequency may be formed by the coupling between the first inductor and the second inductor.

In the electronic component according to the embodiment of the disclosure, the first inductor may be connected to the at least one capacitor.

In the electronic component according to the embodiment of the disclosure, a capacitor that is connected in series to the first inductor may not be provided between the first path and the ground.

The electronic component according to the embodiment of the disclosure may further include a circuit including the second inductor. The circuit may include an element that is provided between the LC circuit and the second inductor.

In the electronic component according to the embodiment of the disclosure, the LC circuit may include a third path that connects the first path and the second path to each other. The at least one capacitor may include a first capacitor and a second capacitor that are provided to the third path, and a third capacitor that is connected to the first capacitor and the second capacitor. The at least one inductor may be a third inductor that is provided between the third path and the ground.

In the electronic component according to the embodiment of the disclosure, the first inductor may include a first part and a second part that is provided between the first part and the ground. The second inductor may include a third part and a fourth part that is provided between the third part and the ground. An interval between the second part and the fourth part may be smaller than an interval between the first part and the third part.

In the electronic component according to the disclosure, the first inductor and the second inductor are physically arranged so as to be coupled to each other. With this, according to the disclosure, an electronic component that can achieve size reduction while achieving desired characteristics can be provided.

It is apparent that the disclosure can be carried out in various forms and modifications in the light of the foregoing descriptions. Accordingly, within the scope of the following claims and equivalents thereof, the disclosure can be carried out in forms other than the foregoing example embodiments.

1. An electronic component comprising:
a first signal port;
a second signal port;
an LC circuit that is provided between the first signal port and the second signal port, includes at least one capacitor and at least one inductor, and is configured to cause a signal having a frequency equal to or higher than a specific frequency to pass through selectively;
a first path that extends from the first signal port to the LC circuit;
a second path that extends from the second signal port to the LC circuit;
a first inductor that is provided between the first path and a ground; and
a second inductor that is provided between the second path and the ground, wherein
the first inductor and the second inductor are physically arranged so as to be coupled to each other.

2. The electronic component according to claim 1, wherein
the LC circuit, the first inductor, and the second inductor form a plurality of attenuation poles in a stop band of pass attenuation characteristics between the first signal port and the second signal port, the stop band being lower than the specific frequency, and
among the plurality of attenuation poles, an attenuation pole having the lowest frequency is formed by the coupling between the first inductor and the second inductor.

3. The electronic component according to claim 1, wherein
the first inductor is connected to the at least one capacitor.

4. The electronic component according to claim 1, wherein
a capacitor that is connected in series to the first inductor is not provided between the first path and the ground.

5. The electronic component according to claim 1, further comprising:
another circuit that includes the second inductor, wherein the other circuit includes an element that is provided between the LC circuit and the second inductor.

6. The electronic component according to claim 1, wherein
the LC circuit includes a third path that connects the first path and the second path to each other,
the at least one capacitor includes a first capacitor and a second capacitor that are provided to the third path, and a third capacitor that is connected to the first capacitor and the second capacitor, and
the at least one inductor is a third inductor that is provided between the third path and the ground.

7. The electronic component according to claim 1, wherein
the first inductor includes a first part and a second part that is provided between the first part and the ground,
the second inductor includes a third part and a fourth part that is provided between the third part and the ground, and
an interval between the second part and the fourth part is smaller than an interval between the first part and the third part.
